(19) United States
(12) Patent Application Publication
(10) Pub. No.: US 2013/0016474 A1
(43) Pub. Date: Jan. 17, 2013

(54) HEAT DISSIPATING ASSEMBLY OF PHOTOVOLTAIC JUNCTION BOX

(71) Applicants: CHIH-CHAN GER, Jhongli City (TW); YU-HSIANG LIAO, Jhongli City (TW); SHANG-TING CHEN, Jhongli City (TW); TSUNG-LIANG HUNG, Jhongli City (TW)

(72) Inventors: CHIH-CHAN GER, Jhongli City (TW); YU-HSIANG LIAO, Jhongli City (TW); SHANG-TING CHEN, Jhongli City (TW); TSUNG-LIANG HUNG, Jhongli City (TW)

(73) Assignee: AMPOWER TECHNOLOGY CO., LTD., Jhongli City (TW)

(21) Appl. No.: 13/426,609

(22) Filed: Mar. 22, 2012

(30) Foreign Application Priority Data
Jul. 11, 2011 (TW) 100212641

(51) Int. Cl. H05K 7/20; H05K 7/00

(52) U.S. Cl. 361/707; 361/752

(57) ABSTRACT

A photovoltaic junction box includes a housing, a circuit board received in the housing, a plurality of metal brackets, and a plurality of bypass diodes. The plurality of metal brackets are secured to the circuit board. The plurality of bypass diodes are respectively secured to the plurality of metal brackets and electrically connected to the circuit board.

### BACKGROUND

1. Technical Field

The present disclosure generally relates to photovoltaic (PV) junction boxes, and more particularly to a heat dissipating assembly of a PV junction box.

2. Description of Related Art

A photovoltaic (PV) power generation system comprises a plurality of PV panels connected together through cables and PV junction boxes. One of the plurality of PV panels is electrically connected to a circuit board of a PV junction box via a plurality of ribbons soldered onto the circuit board. The PV junction box is structured on one corresponding PV panel and comprises a plurality of bypass diodes configured on the circuit board. The bypass diodes generate heat when the PV panel could not receive solar radiations, and an overheated bypass diode may damage the PV junction box. Furthermore, the ribbons are prone to fall off from the circuit board of the PV junction box due to mis-soldering between the ribbons and the circuit board.

Therefore, a need exists in the industry to overcome the described problems.

### BRIEF DESCRIPTION OF THE DRAWINGS

Many aspects of the present embodiments can be better understood with reference to the following drawings. The components in the drawings are not necessarily drawn to scale, the emphasis instead being placed upon clearly illustrating the principles of the present embodiments. Moreover, in the drawings, all the views are schematic, and like reference numerals designate corresponding parts throughout the several views.

FIG. 1 is a perspective view of a photovoltaic (PV) junction box of a first exemplary embodiment of the disclosure, showing an inner structure of the PV junction box.

FIG. 2 is a perspective view of a circuit board of the PV junction box of FIG. 1.

FIG. 3 is an enlarged view showing exemplary relationships among a plurality of ribbons, a plurality of fixing mechanisms, and the circuit board.

FIG. 4 is an inverted view of FIG. 3.

FIG. 5 is an exploded view of an exemplary embodiment of one of the plurality of fixing mechanisms of the PV junction box of FIG. 1.

FIG. 6 is similar to FIG. 5, but viewed from a different aspect.

FIG. 7 is an assembled view of the one of the plurality of fixing mechanisms of FIG. 5.

FIG. 8 is a sectional view of FIG. 7.

FIG. 9 is similar to FIG. 8, but showing a ribbon secured to the fixing mechanism of FIG. 8.

FIG. 10 is a schematic diagram of the PV junction box of FIG. 1, showing a first current flow direction of the PV junction box in a normal functional state, but not showing the housing of the PV junction box.

FIG. 11 is a sectional and enlarged view of FIG. 10.

FIG. 12 is a schematic diagram of the PV junction box of FIG. 1, showing a second current flow direction of the PV junction box in an abnormal functional state, but not showing the housing of the PV junction box.

FIG. 13 is a partially and schematic view of a second exemplary embodiment of the PV junction box, showing bypass diodes secured to a sidewall of a metal bracket via resilient elements.

FIG. 14 is a partially and schematic view of a third exemplary embodiment of the PV junction box, showing bypass diodes secured to a sidewall of a metal bracket via screws.

FIG. 15 is a bottom view of the PV junction box of FIG. 13 and FIG. 14, showing the bypass diodes secured to a bottom surface of the circuit board of the PV junction box.

### DETAILED DESCRIPTION

The disclosure is illustrated by way of example and not by way of limitation in the figures of the accompanying drawings, in which like reference numerals indicate similar elements. It should be noted that references to “an” or “one” embodiment in this disclosure are not necessarily to the same embodiment, and such references can mean “at least one” embodiment.

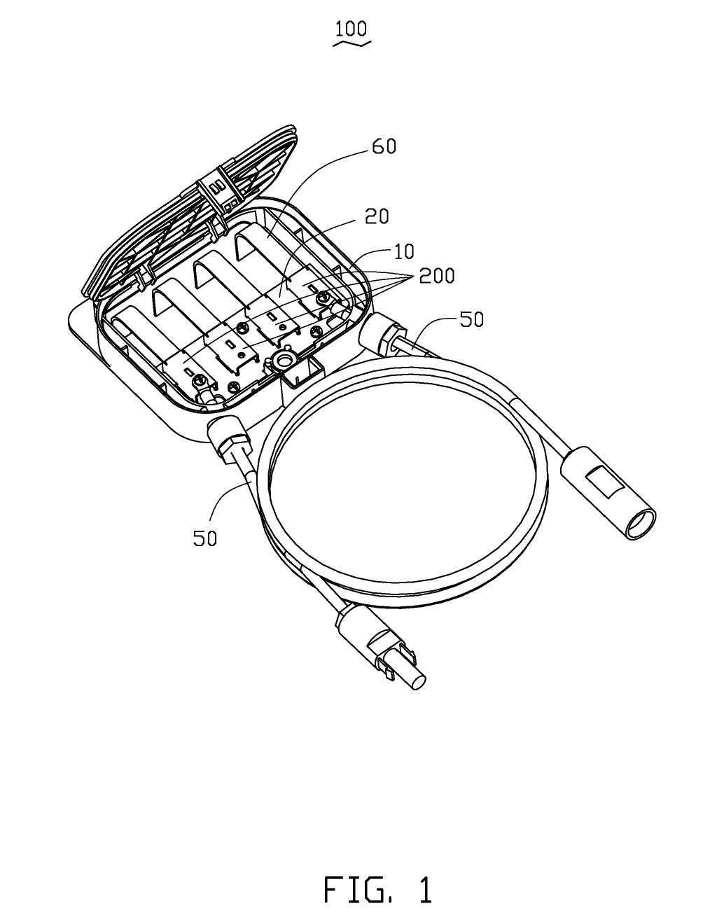

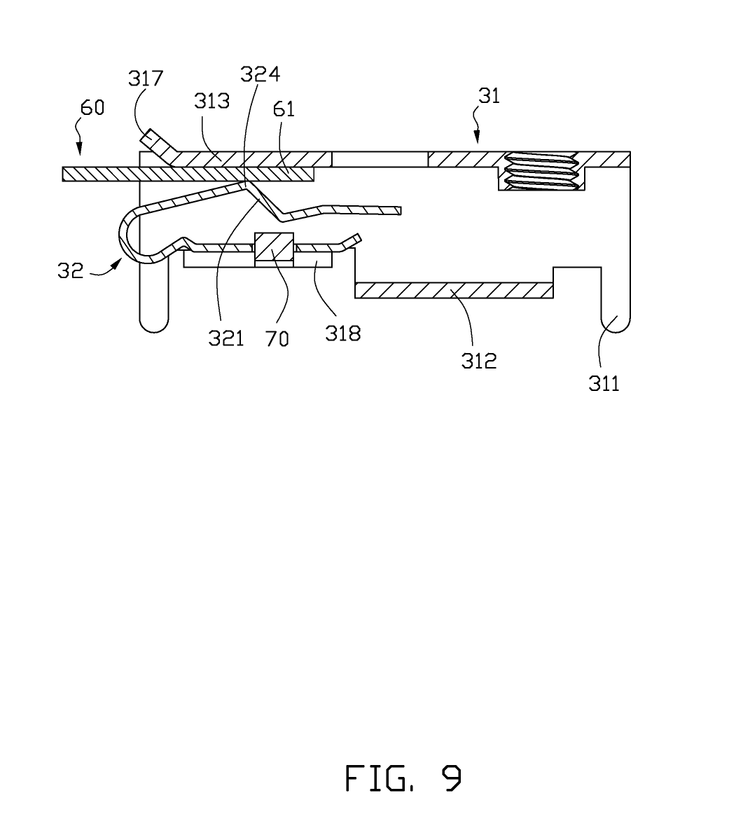

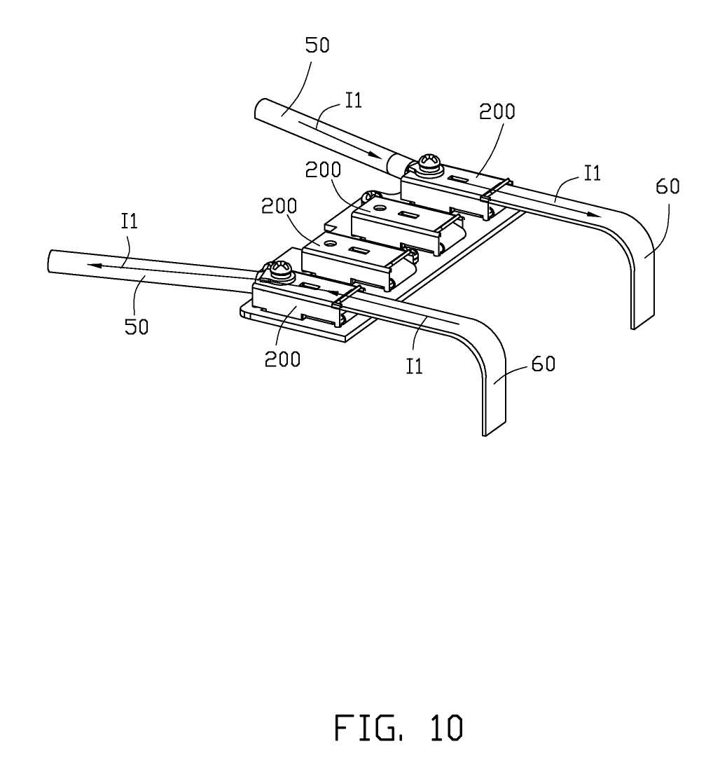

With reference to FIG. 1, a photovoltaic (PV) junction box 100 comprises a housing 10, a circuit board 20 received in the housing 10, a plurality of fixing mechanisms 200 secured to the circuit board 20, and a pair of cables 50 respectively connecting two of the plurality of fixing mechanisms 200 to corresponding two electrical terminals of a power conversion device (not shown), such as an inverter. A plurality of ribbons 60 are respectively and electrically secured to the plurality of fixing mechanisms 200, to electrically connect the circuit board 20 of the PV junction box 100 to a PV panel (not shown). Electrical current flows from the PV panel through the plurality of ribbons 60 to the PV junction box 100, and to the power conversion device by way of the pair of cables 50 (shown in FIG. 9 and FIG. 10).

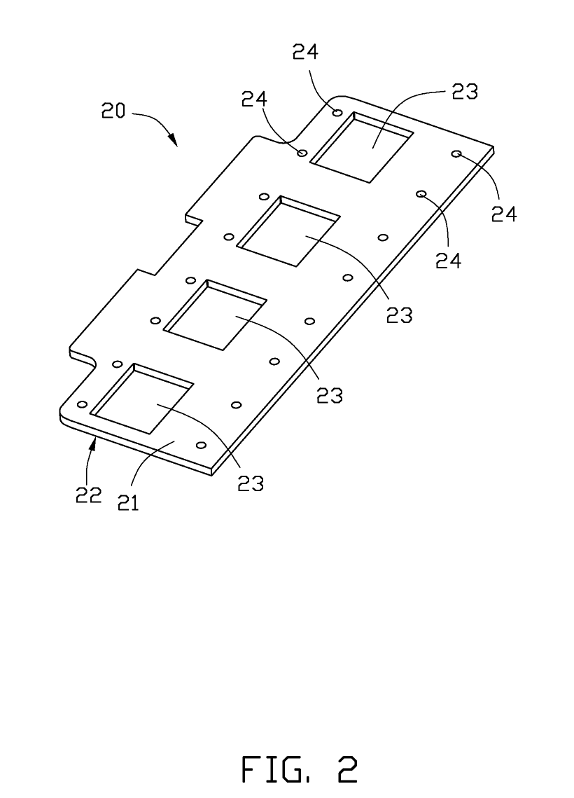

With reference to FIG. 2, the circuit board 20 comprises a top surface 21, a bottom surface 22 opposite to the top surface 21, and a plurality of holes 23 running through the circuit board 20 from the top surface 21 to the bottom surface 22 and corresponding to the plurality of fixing mechanisms 200. A plurality of securing holes 24 are defined on two sides of the plurality of holes 23. In the embodiment, four securing holes 24 match with one of the plurality of holes 23, and are positioned close to four corners of each of the plurality of holes 23. In one example, the plurality of securing holes 24 are divided into four groups and each group has four securing holes 24. Each group of securing holes 24 are positioned close to four corners of each holes 23.

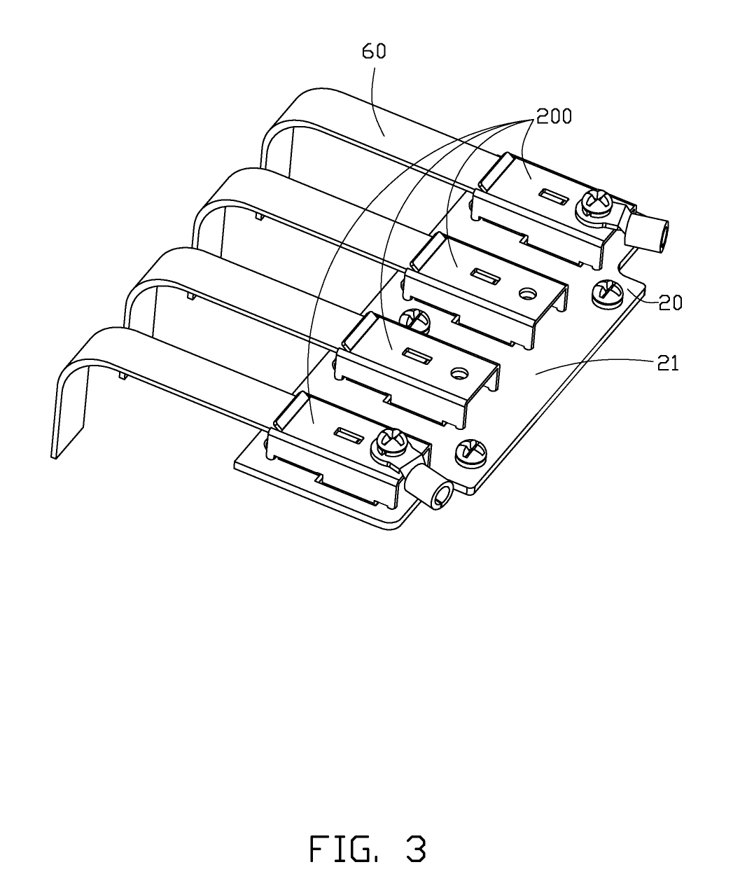

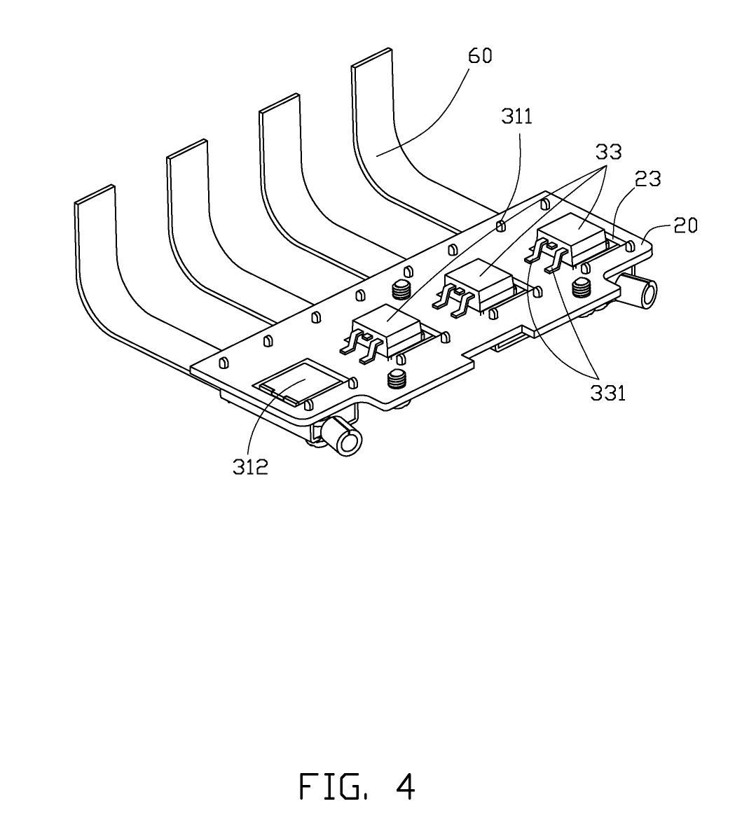

With reference to FIGS. 3-4, the plurality of fixing mechanisms 200 are positioned on the top surface 21 of the circuit board 20. A plurality of bypass diodes 33 are electrically connected to the bottom surface 22 of the circuit board 20 via a pair of feet 331 of the bypass diode 33. The number of the plurality of bypass diodes 33 is one less than the number of the fixing mechanisms 200. In one example, the number of the fixing mechanisms 200 may be four, and the number of the plurality of bypass diodes 33 may be three. Each of the plurality of bypass diodes 33 is secured to one corresponding fixing mechanism 200. Thus, one of the plurality of fixing mechanisms 200 is redundant, and there is no bypass diode 33 fixed on the redundant fixing mechanism 200 which is connected to one of the pair of cables 50, as shown in FIG. 4.

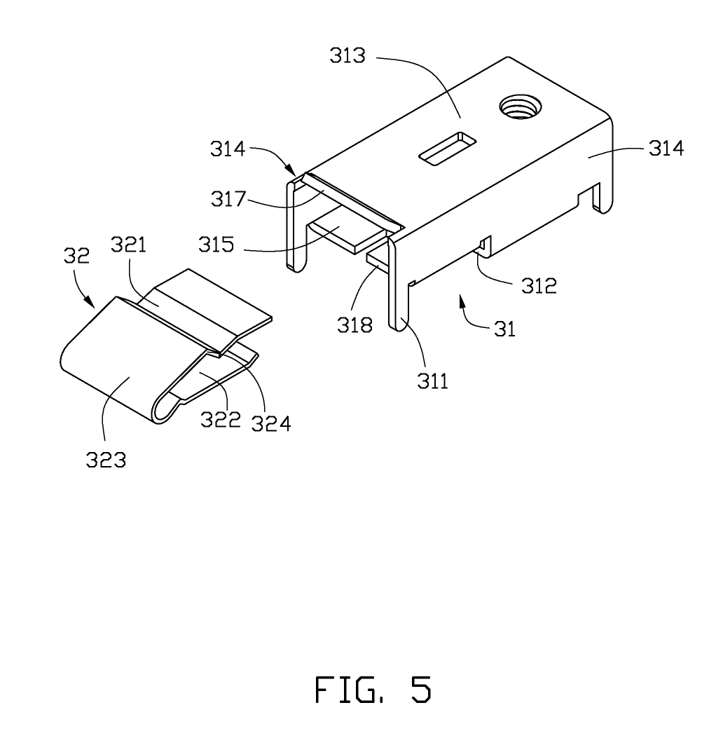

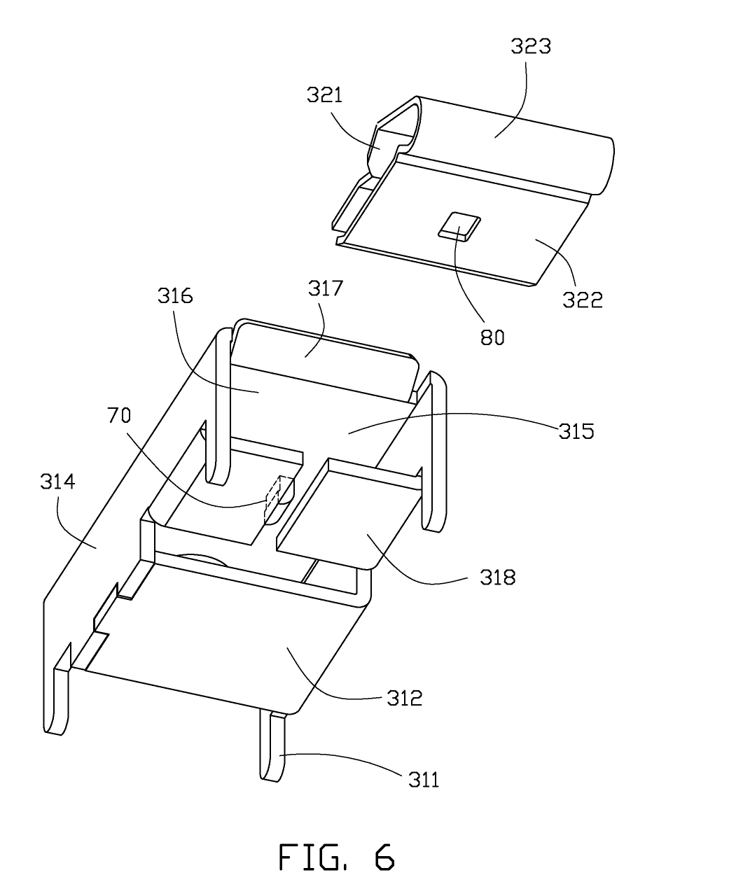

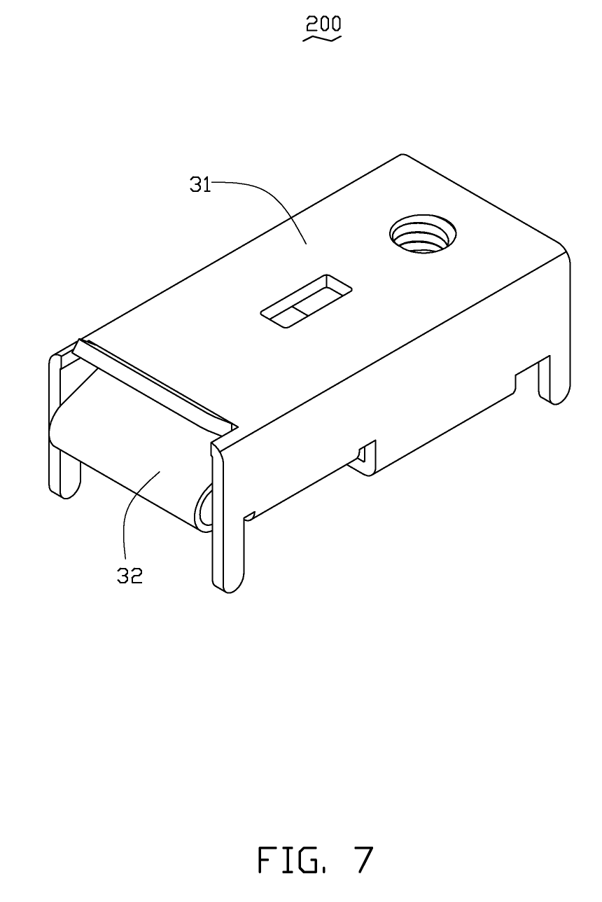

With reference to FIGS. 5-7, each of the plurality of fixing mechanisms 200 comprises a metal bracket 31 and a spring sheet 32 urged in the metal bracket 31. The metal bracket 31 comprises a top wall 313, a first bottom wall 318 and a second bottom wall 312 opposite to the top wall 313, and a pair of sidewalls 314 perpendicularly connected between the top wall 313 and the first, second bottom walls 318, 312. In the embodiment, the second bottom wall 312 keeps a farther distance from the top wall 313 than that of the first bottom wall 318. That is, the first bottom wall 318 and the second bottom wall 312 collectively form a step. The second bottom wall 312, the top wall 313, and the sidewalls 314 collectively define a receiving space 315 having an opening 316 shown in FIG. 6. The metal bracket 31 comprises a plurality of positioning pins 311 extending from the sidewalls 314 of the metal bracket 31, and corresponding to the plurality of securing holes 24 in the circuit board 20.

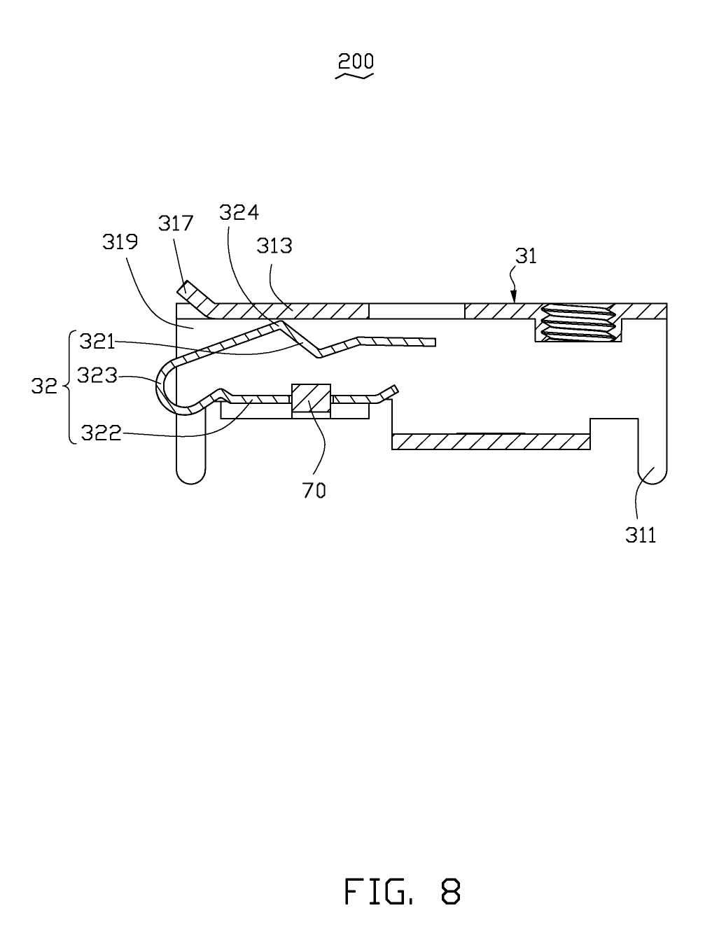

With reference to FIG. 8 also, the spring sheet 32 comprises an extending portion 321, a positioning portion 322 opposite to the extending portion 321, and a connecting portion 323 connecting the extending portion 321 and the positioning portion 322 resiliently. In assembly, the spring sheet 32 is received in the receiving space 315 of the metal bracket 31, a urging portion 324 between the extending portion 321 and the connecting portion 323 resists on the top wall 313 of the metal bracket 31, the positioning portion 322 is secured to the first bottom wall 318, and the connecting portion 323 is partially exposed out of the opening 316 of the metal bracket 31.

In the embodiment, the metal bracket 31 comprises a protrusion 70 extending perpendicularly from the first bottom wall 318 toward the receiving space 315, and the spring sheet 32 defines a positioning hole 80 located on the positioning portion 322. In assembly, the protrusion 70 on the metal bracket 31 engages with the positioning hole 80 of the spring sheet 32 to secure the spring sheet 32 to the metal bracket 31 firmly.

In the embodiment, a tail end 317 of the top wall 313 is tilted away from the opening 316 of the metal bracket 31, and the connecting portion 323 of the spring sheet 32 is substantially arc-shaped and corresponds to the tail end 317 of the top wall 313. As a result, an inserting opening 319 having a wedge shape is formed between the connecting portion 323 of the spring sheet 32 and the top wall 313 of the metal bracket 31, as shown in FIG. 8. Because of the wedge shape of the inserting opening 319, the ribbons 60 are prone to be inserted into and clamped between the top wall 313 of the metal bracket 31 and the urging portion 324 of the spring sheet 32, as shown in FIG. 9. Therefore, the fixing mechanism 200 can apply to various PV junction boxes 100 with different power, regardless of a thickness of the ribbon 60 of the PV junction box 100 varying according to power of the PV junction box 100.

In assembly of the PV junction box 100, the plurality of positioning pins 311 of the metal bracket 31 of each of the plurality of fixing mechanisms 200 are respectively plugged in corresponding securing holes 24 of the circuit board 20 and are soldered on the circuit board 20 to position the corresponding fixing mechanism 200 on the circuit board 20. The second bottom wall 312 of the metal bracket 31 of each of the plurality of fixing mechanism 200 is inserted into a corresponding hole 23 in the circuit board 20 from the top surface 21 of the circuit board 20 and is coplanar with the bottom surface 22 of the circuit board 20, and the first bottom wall 318 abuts the top surface 21 of the circuit board 20. Each of the plurality of bypass diodes 33 is secured to a corresponding one of the fixing mechanism 200 and contacts the second bottom wall 312 of the metal bracket 31 of the corresponding fixing mechanism 200. Each bypass diode 33 is electrically connected to the circuit board 20 via the pair of feet 331 of the bypass diode 33. The plurality of ribbons 60 are respectively secured to the plurality of fixing mechanisms 200. An inserting portion 61 of each of the plurality of ribbons 60 is clamped between the urging portion 324 of the spring sheet 32 and the top wall 313 of the metal bracket 31 of a corresponding fixing mechanism 200, as shown in FIG. 9. With this assembled structure, each of the plurality of ribbons 60 directly and electrically contacts a corresponding metal bracket 31.

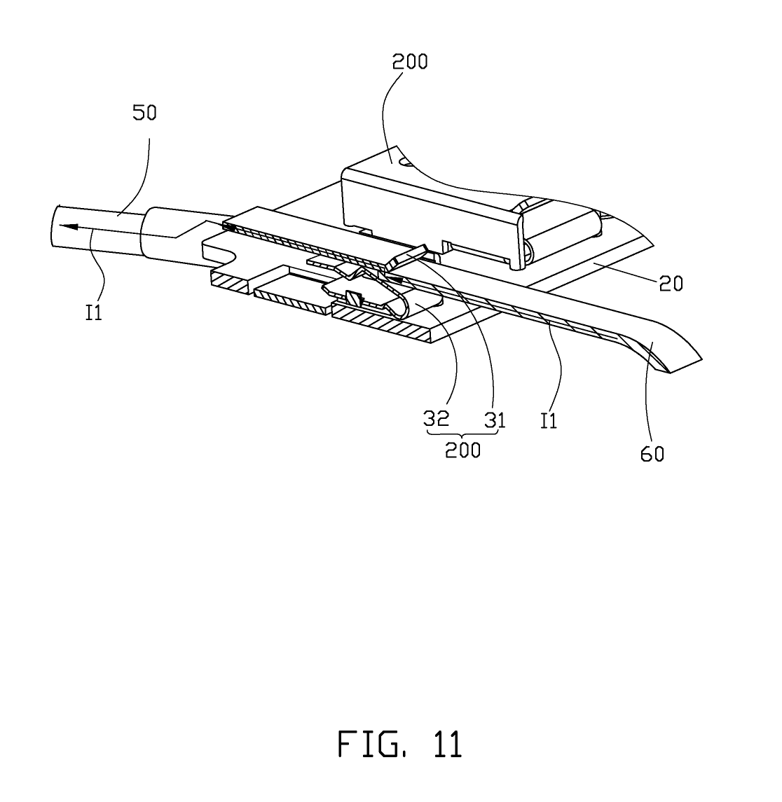

FIG. 10 shows a first current flow (labeled as Il) direction of the PV junction box 100 in a normal functional state. Because each of the plurality of ribbons 60 is clamped between the metal bracket 31 and the spring sheet 32 of one corresponding fixing mechanism 200 and directly contacts the metal bracket 31, as shown in FIG. 11, the first current flow I1 flows through the metal bracket 31 directly, the metal bracket 31 is configured as a bridge for conducting the first current flow I1 between the ribbon 60 and the cable 50 in the normal function state of the PV junction box 100.

In the embodiment, the metal bracket 31 can be made of a conductive material that has a good conductivity and a low resistance (e.g., copper). The metal bracket 31 is configured as the bridge for conducting the first current flow I1, which results in low contact resistance of the PV junction box 100 and improves reliability of the PV junction box 100.

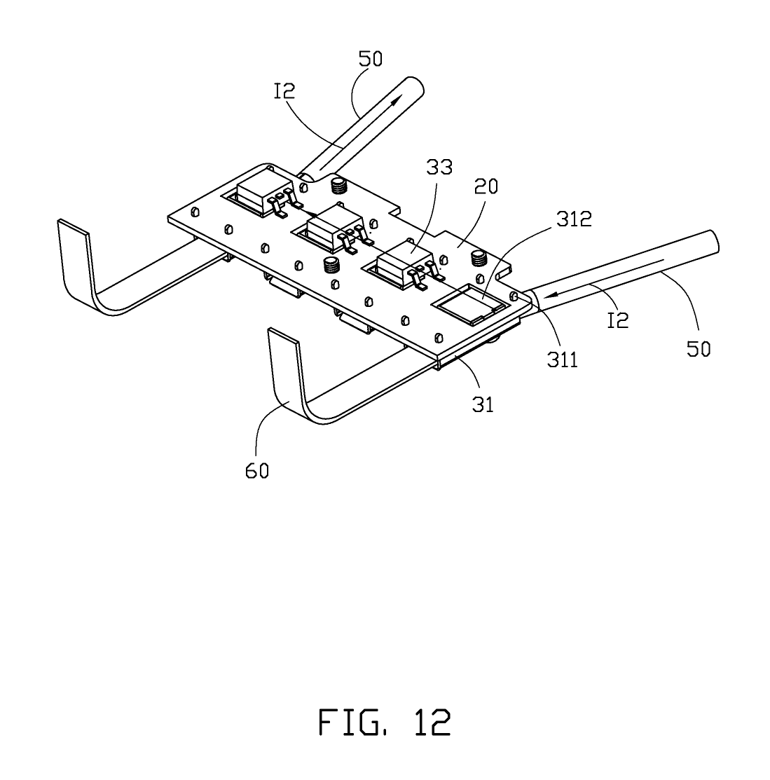

FIG. 12 shows a second current flow (labeled as I2) direction of the PV junction box 100 in an abnormal functional state. In the embodiment, the PV junction box 100 functions abnormally, because the PV panel could not receive solar radiation. In the abnormal functional state, the plurality of bypass diodes 33 are conducted, and the second current flow I2 flows through the plurality of bypass diodes 33. As a result, the plurality of bypass diodes 33 are heated. The metal bracket 31 is configured to dissipate heat generated by the bypass diodes 33 because each of the plurality of bypass diodes 33 contacts the second bottom wall 312 of the metal bracket 31 of one corresponding fixing mechanism 200. With this structure, the PV junction box 100 maintains a low temperature and low conduction loss even if the PV panel could not receive the solar radiation, due to the metal bracket 31 dissipating heat generated by the plurality of bypass diodes 33. As a result, the housing 10 of the PV junction box 100 is prevented from being deformed or cracked in the abnormal functional state of the PV junction box 100.

In the embodiment, the metal bracket 31 is configured as a three dimensional structure, which increases heat dissipating area for the bypass diodes 33.

In the embodiment, the top wall 313, the first bottom wall 318, the second bottom wall 312, and the sidewalls 314 of the metal bracket 31 are integrally formed, thus, the metal bracket 31 endures elasticity of the spring sheet 32 and is resistant to deformation. In addition, each of the plurality of ribbons 60 is manually clamped between the metal bracket 31 and the spring sheet 32 of a corresponding fixing mechanism 200, which leads to convenience of installing the ribbons 60.

In the embodiment, each of the plurality of bypass diodes 33 is soldered on the second bottom wall 312 of the metal bracket 31 of a corresponding fixing mechanism 200 via a furnacing process, which could prevent generating voids between the second bottom wall 312 of the metal bracket 31 and the bypass diode 33 and gets improvement of productivity of the PV junction box 100. In addition, because heat generated by the bypass diodes 33 is dissipated by the metal brackets 31 of the fixing mechanisms 200, the circuit board 20 of the PV junction box 100 can be made of materials with a low heat resistant grade, which also reduces cost.

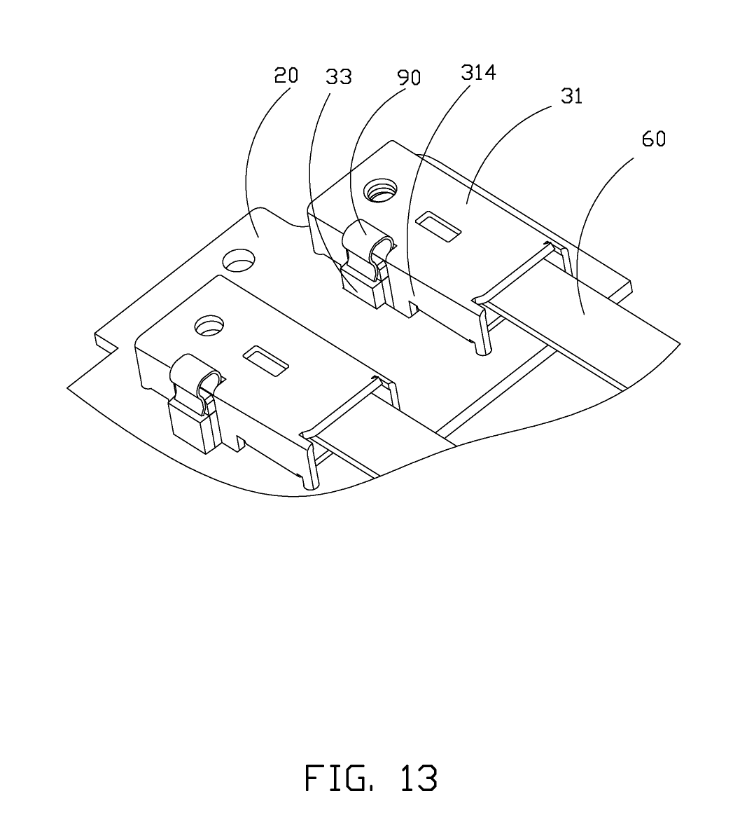

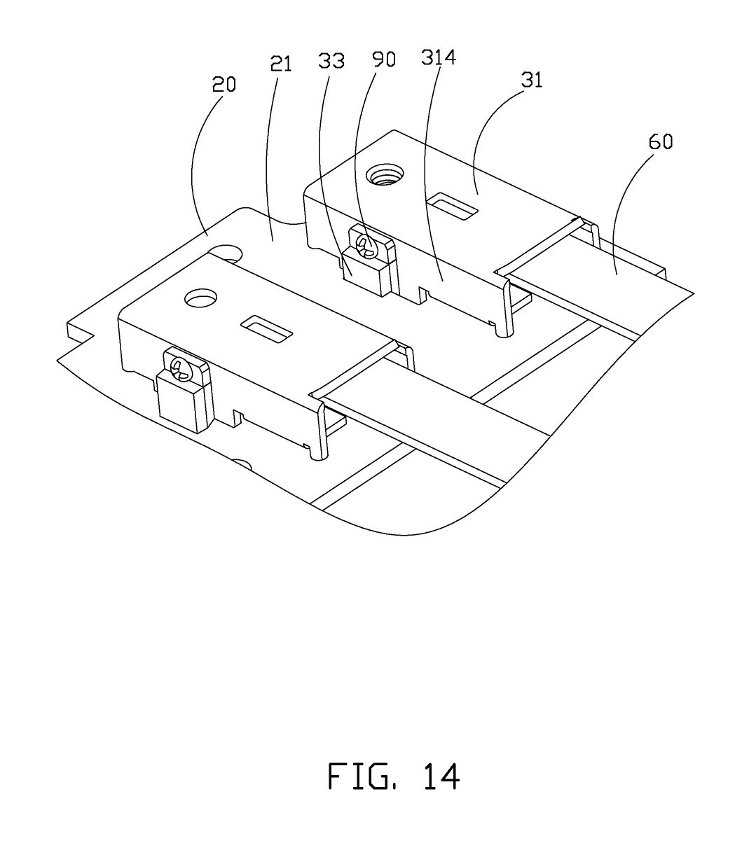

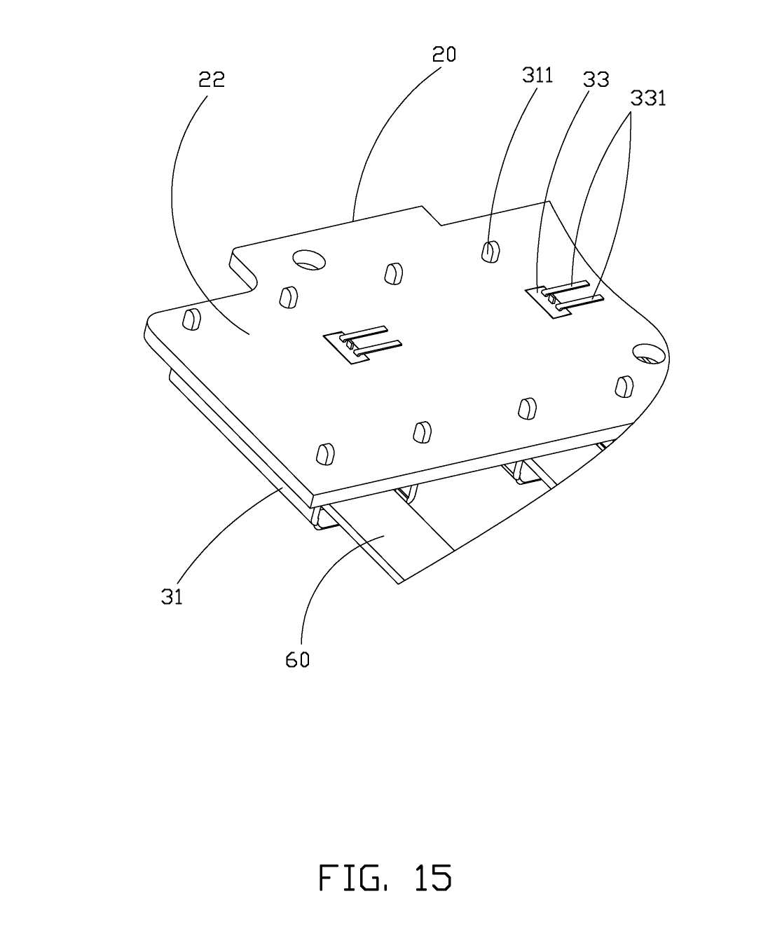

With reference to FIGS. 13-15, in an alternative embodiment, each of the plurality of bypass diodes 33 contacts the sidewall 314 of the metal bracket 31 of a corresponding fixing mechanism 200. The bypass diodes 33 is secured to the metal bracket 31 by a fixing part 90, and the pair of feet 331 of the bypass diode 33 is inserted from the top surface 21 of the circuit board 20 to the bottom surface 22 of the circuit board 20 and electrically connected to the circuit board 20, as shown in FIG. 15. In the embodiment, the fixing part 90 is a clip, and the clip clamps the bypass diode 33 and the metal bracket 31 together, as shown in FIG. 13. In another embodiment, the fixing part 90 may be a screw, as shown in FIG. 14.

Although the features and elements of the present disclosure are described as embodiments in particular combinations, each feature or element can be used alone or in other various combinations within the principles of the present disclosure to the full extent indicated by the broad general meaning of the terms in which the appended claims are expressed.

What is claimed is:

1. A heat dissipating assembly of a photovoltaic junction box, comprising:
a circuit board defining a plurality of holes and received in the photovoltaic junction box;
a plurality of metal brackets corresponding to the plurality of holes of the circuit board and secured to the circuit board, each of the plurality of metal brackets comprising a first bottom wall received in a corresponding hole of the circuit board;
a plurality of bypass diodes electrically connected to the circuit board, and respectively secured to the first bottom walls of the plurality of metal brackets.

2. The heat dissipating assembly of the photovoltaic junction box of claim 1, wherein the circuit board comprises a top surface and a bottom surface opposite to the top surface, the first bottom wall of each of the plurality of metal brackets is inserted into a corresponding hole of the circuit board from the top surface of the circuit board and coplanar with the bottom surface of the circuit board.

3. The heat dissipating assembly of the photovoltaic junction box of claim 2, wherein each of the plurality of metal brackets comprises a second bottom wall, the second bottom wall and first bottom wall collectively form a step, and the second bottom wall resists the top surface of the circuit board.

4. The heat dissipating assembly of the photovoltaic junction box of claim 3, wherein each of the plurality of metal brackets comprises a top wall opposite to the first bottom wall and the second bottom wall, and a pair of sidewalls perpendicularly connected between the top wall and the first and second bottom walls, and wherein the top wall, the first and second bottom walls and the pair of sidewalls collectively define a receiving space.

5. The heat dissipating assembly of the photovoltaic junction box of claim 4, wherein a plurality of ribbons are respectively secured to the receiving spaces of the plurality of metal brackets, the plurality of ribbons are electrically connected between a photovoltaic panel and the photovoltaic junction box.

6. A heat dissipating assembly of a photovoltaic junction box, comprising:
a circuit board comprising a top surface and a bottom surface opposite to the top surface;
a plurality of metal brackets secured to the top surface of the circuit board, each of the plurality of metal brackets comprising a pair of sidewalls;
a plurality of bypass diodes partially and respectively inserted through the circuit board from the top surface of the circuit board and coplanar to the bottom surface of the circuit board, each of the plurality of bypass diodes electrically connected to the bottom surface of the circuit board via a pair of feet of the bypass diode and secured to one of the pair of sidewalls of a corresponding metal bracket.

7. The heat dissipating assembly of the photovoltaic junction box of claim 6, wherein each of the plurality of metal brackets comprises a top wall and a second bottom wall opposite to the top wall, the pair of sidewalls, the top wall and the second bottom wall collectively defining a receiving space.

8. The heat dissipating assembly of the photovoltaic junction box of claim 7, wherein a plurality of ribbons are respectively secured to the receiving spaces of the plurality of metal brackets, the plurality of ribbons are electrically connected between a photovoltaic panel and the photovoltaic junction box.

9. A photovoltaic junction box, comprising:
a housing;
a circuit board received in the housing;
a plurality of metal brackets secured to the circuit board;
a plurality of bypass diodes respectively secured to the plurality of metal brackets and electrically connected to the circuit board; and
a plurality of spring sheet respectively secured to the plurality of metal brackets to clamp a plurality of ribbons.

10. The photovoltaic junction box of claim 9, each of the plurality of bypass diodes is soldered on a corresponding metal bracket.

11. The photovoltaic junction box of claim 9, each of the plurality of bypass diodes is secured to a corresponding metal bracket by a screw.

12. The photovoltaic junction box of claim 9, each of the plurality of bypass diodes is secured to a corresponding metal bracket by a clip.

13. The photovoltaic junction box of claim 9, each of the plurality of metal brackets is soldered on the circuit board.
